(19) United States
(12) Patent Application Publication
(10) Pub. No.: US 2025/0166430 A1
(43) Pub. Date: May 22, 2025

(54) VEHICLE HAVING RELAY WELDING DIAGNOSIS FUNCTION AND RELAY WELDING DIAGNOSIS METHOD PERFORMED IN THE VEHICLE

(71) Applicants: HYUNDAI MOTOR COMPANY, Seoul (KR); Kia Corporation, Seoul (KR)

(72) Inventors: Jae Hun Jeong, Anyang-si (KR); Mun Soo Chung, Uiwang-si (KR); Kyu Won Jeong, Hwaseong-si Gyeonggi-do (KR); Tae Woo Kim, Anyang-si (KR); Jong Dae Kim, Anyang-si (KR); Beom Sik Kim, Gwangmyeong-si (KR); Sang Don Lee, Suwon-si (KR)

(73) Assignees: HYUNDAI MOTOR COMPANY, Seoul (KR); Kia Corporation, Seoul (KR)

(21) Appl. No.: 18/815,638

(22) Filed: Aug. 26, 2024

(30) Foreign Application Priority Data
Nov. 20, 2023 (KR) 10-2023-0160934

(51) Int. Cl. G07C 5/08; B60L 53/54; B60L 53/60; H01M 10/42; H01M 10/44; H01M 10/46; H01M 16/00

(52) U.S. Cl. CPC G07C 5/0808; B60L 53/54; B60L 53/60; H01M 10/4264; H01M 10/44; H01M 10/46; H01M 16/006; H01M 2010/4271; H01M 2220/20; H01M 2250/20; H01M 2250/402

(57) ABSTRACT

A vehicle including a relay welding diagnosis function and a relay welding diagnosis method performed in the vehicle, is configured to be connectable to a charger providing a charging voltage, and includes a fuel cell configured to provide a stack voltage, a multi-converter configured to increase the level of the charging voltage or the stack voltage and to output the charging voltage or the stack voltage having the increased level as a boosted voltage, a charging relay disposed between the charger and the multi-converter, and a battery configured to store electrical energy of the boosted voltage. The multi-converter includes a voltage booster connected between the charging relay and the battery and configured to generate the boosted voltage and a converter controller configured to diagnose whether the charging relay is welded using a result of sensing an input-terminal voltage and an output-terminal voltage of the charging relay.

### CROSS-REFERENCE TO RELATED APPLICATION

The present application claims priority to Korean Patent Application No. 10-2023-0160934, filed on Nov. 20, 2023, the entire contents of which is incorporated herein for all purposes by this reference.

### BACKGROUND OF THE PRESENT DISCLOSURE

### Field of the Present Disclosure

The present disclosure relates to a vehicle including a relay welding diagnosis function and a relay welding diagnosis method performed in the vehicle.

### Description of Related Art

A currently mass-produced hydrogen fuel cell vehicle utilizes a hydrogen fuel cell and a high-voltage battery as power sources. Energy generated by the hydrogen fuel cell is boosted using a fuel cell DC-DC converter (FDC) disposed between the hydrogen fuel cell and the high-voltage battery, and the boosted energy is supplied to a motor, or the high-voltage battery is charged with the boosted energy. However, excessive use of the high-voltage battery may make it impossible to implement EV driving using the high-voltage battery or initial start of the fuel cell, and as a result, the vehicle may become inoperative.

To prevent the vehicle from becoming inoperative due to insufficient energy in the high-voltage battery, it is necessary to stably maintain the state of charge (SOC) value of the high-voltage battery through additional charging of the high-voltage battery. To the present end, studies have been conducted to diagnose whether a charging relay selectively connecting a charger to an FDC is welded in a vehicle having both an FDC function and a charging function.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a vehicle including a relay welding diagnosis function and a relay welding diagnosis method performed in the vehicle that substantially obviate one or more problems due to limitations and disadvantages of the related art.

Embodiments provide a vehicle configured for accurately diagnosing whether a charging relay is welded and a relay welding diagnosis method performed in the vehicle.

However, the objects to be accomplished by the exemplary embodiments are not limited to the above-mentioned objects, and other objects not mentioned herein will be clearly understood by those skilled in the art from the following description.

Additional advantages, objects, and features of the present disclosure will be set forth in part in the description which follows and in part will become apparent to those having ordinary skill in the art upon examination of the following or may be learned from practice of the present disclosure. The objectives and other advantages of the present disclosure may be realized and attained by the structure particularly pointed out in the written description and claims hereof as well as the appended drawings.

According to an exemplary embodiment of the present disclosure, a vehicle configured to be connectable to a charger providing a charging voltage may include a fuel cell configured to provide a stack voltage, a multi-converter configured to increase a level of the charging voltage or the stack voltage and to output the charging voltage or the stack voltage having the increased level as a boosted voltage, a charging relay disposed between the charger and the multi-converter, and a battery configured to store electrical energy of the boosted voltage, wherein the multi-converter may include a voltage booster connected between the charging relay and the battery and configured to generate the boosted voltage and a converter controller configured to diagnose whether the charging relay is welded using a result of sensing an input-terminal voltage and an output-terminal voltage of the charging relay.

In an exemplary embodiment of the present disclosure, the vehicle may further include a mode switching unit configured to selectively connect the fuel cell to the multi-converter.

In an exemplary embodiment of the present disclosure, the vehicle may further include a high-level controller configured to control ON/OFF of the charging relay and the mode switching unit and to control the converter controller to diagnose whether the charging relay is welded.

In an exemplary embodiment of the present disclosure, the multi-converter may further include a first capacitor connected between the voltage booster and the charging relay.

In an exemplary embodiment of the present disclosure, the multi-converter may further include a second capacitor connected between the voltage booster and the battery.

In an exemplary embodiment of the present disclosure, the vehicle may further include a battery management system configured to check whether charging of the battery ends normally, to output a checking result to the high-level controller, and to control ON/OFF of a main relay included in the battery.

According to another exemplary embodiment of the present disclosure, a relay welding diagnosis method performed in the vehicle described above may include controlling an output-terminal current of the charging relay depending on whether charging operation of the charger ends normally, turning the charging relay off, and diagnosing whether the charging relay is welded by adjusting a level of a first voltage measured at an output terminal of the charging relay to a target value and using a difference in level between a second voltage measured again at the output terminal of the charging relay and a third voltage measured at an input terminal of the charging relay.

In an exemplary embodiment of the present disclosure, the controlling an output-terminal current may include checking whether the charging operation ends normally or abruptly, setting the output-terminal current to 0 amperes when the charging operation has ended normally, and checking whether the output-terminal current is less than a predetermined current level when the charging operation has ended abruptly.

In an exemplary embodiment of the present disclosure, the diagnosing whether the charging relay is welded may include controlling the level of the first voltage to the target value, measuring the second voltage, checking whether an absolute value of the difference in level between the second voltage and the third voltage is greater than or equal to a predetermined value, determining that the charging relay has been turned off normally when the absolute value is greater than or equal to the predetermined value, and determining that the charging relay has been welded when the absolute value is less than the predetermined value.

In an exemplary embodiment of the present disclosure, the target value may correspond to half the level of the first voltage.

In an exemplary embodiment of the present disclosure, the diagnosing whether the charging relay is welded may further include notifying that the charging relay has been welded.

In an exemplary embodiment of the present disclosure, the relay welding diagnosis method may further include, after the diagnosing whether the charging relay is welded, determining that charging operation of the charger has been completed.

In an exemplary embodiment of the present disclosure, the relay welding diagnosis method may further include turning the main relay off.

In an exemplary embodiment of the present disclosure, the relay welding diagnosis method may further include discharging the first capacitor.

It is to be understood that both the foregoing general description and the following detailed description of the present disclosure are exemplary and explanatory and are intended to provide further explanation of the present disclosure as claimed.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a block diagram of a vehicle including a relay welding diagnosis function according to an exemplary embodiment of the present disclosure;

FIG. 2 is a circuit diagram of embodiments of the charger and the vehicle shown in FIG. 1; and

FIG. 3 is a flowchart for explaining a relay welding diagnosis method according to an exemplary embodiment of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

The present disclosure will now be described more fully hereinafter with reference to the accompanying drawings, in which various exemplary embodiments of the present disclosure are shown. The examples, however, may be embodied in many different forms, and should not be construed as being limited to the exemplary embodiments set forth herein. Rather, these embodiments are provided so that the present disclosure will be more thorough and complete, and will more fully convey the scope of the present disclosure to those skilled in the art.

It will be understood that when an element is referred to as being “on” or “under” another element, it may be directly on/under the element, or one or more intervening elements may also be present.

When an element is referred to as being “on” or “under”, “under the element” as well as “on the element” may be included based on the element.

Furthermore, relational terms, such as “first”, “second”, “on/upper part/above”, and “under/lower part/below”, are used only to distinguish between one subject or element and another subject or element, without necessarily requiring or involving any physical or logical relationship or sequence between the subjects or elements.

Hereinafter, a vehicle 200 or 200A including a relay welding diagnosis function and a relay welding diagnosis method 400 performed in the vehicle according to various exemplary embodiments will be described with reference to the accompanying drawings.

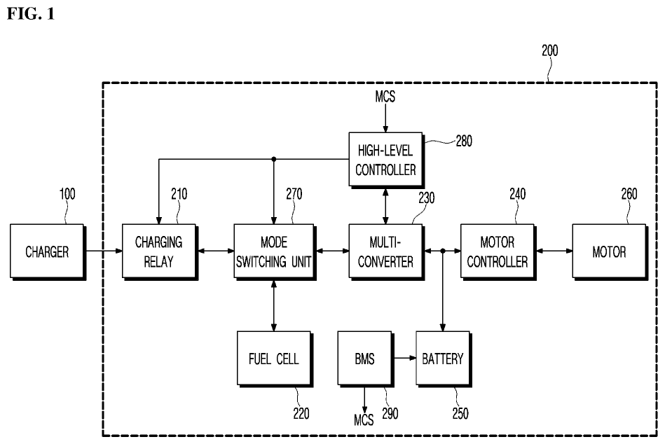

FIG. 1 is a block diagram of a vehicle 200 including a relay welding diagnosis function according to an exemplary embodiment of the present disclosure.

The vehicle 200 shown in FIG. 1 may be connected to and charged by a charger 100. That is, the charger 100 is an energy source which is provided outside the vehicle 200 rather than being mounted in the vehicle 200. The charger 100 may be, for example, a fast charger (or high-speed charger) or a slow charger. The charger 100 may be connected to the vehicle 200 to supply a voltage (hereinafter referred to as a “charging voltage”) to the vehicle 200, and the vehicle 200 may be charged with the charging voltage.

According to an exemplary embodiment of the present disclosure, the vehicle 200 may include a charging relay 210, a fuel cell (or fuel cell stack) 220, a multi-converter 230, a motor controller 240, a battery (or high-voltage battery) 250, a motor 260, a mode switching unit 270, a high-level controller 280, and a battery management system (BMS) 290.

The fuel cell 220 is configured to generate a voltage (hereinafter referred to as a “stack voltage”). That is, the fuel cell 220 may generate power through chemical reaction between oxygen and hydrogen, and may output a stack voltage corresponding to the generated power.

For example, the fuel cell 220 may be a polymer electrolyte membrane fuel cell (or proton exchange membrane fuel cell) (PEMFC). However, the present disclosure is not limited thereto.

The multi-converter 230 may increase the level of the charging voltage or the stack voltage (i.e., boost the voltage), and may transmit the voltage having the increased level (hereinafter referred to as the “boosted voltage”) to the battery 250 or to a load in the vehicle 200, e.g., the motor 260, through the motor controller 240. That is, the boosted voltage output from the multi-converter 230 may be used to drive the motor 260, or may be used to charge the battery 250.

For example, the level of the voltage charged in the battery 250 may be 800 volts, the level of the stack voltage generated by and output from the fuel cell 220 may be 350 volts, and the level of the charging voltage provided from the charger 100 may be 400 volts. In the instant case, the multi-converter 230 may boost the stack voltage of 350 volts or the charging voltage of 400 volts to 800 volts, and may charge the battery 250 with the boosted voltage of 800 volts. However, when the level of the charging voltage is 800 volts, the charging voltage may not be boosted by the multi-converter 230, and the battery 250 may be directly connected to the charger 100 to be charged with the charging voltage of 800 volts.

In the present way, the multi-converter 230 according to the exemplary embodiment of the present disclosure may function as a boosting-type DC-DC converter.

Furthermore, the multi-converter 230 may receive power from the battery 250, and may supply the received power to the fuel cell 220 so that the fuel cell 220 operates. That is, the power supplied from the multi-converter 230 to the fuel cell 220 may be power necessary to drive the fuel cell 220.

The charging relay 210 is disposed between the charger 100 and the multi-converter 230 and is configured to selectively connect the charger 100 to the multi-converter 230.

The mode switching unit 270 is disposed between the multi-converter 230 and each of the charging relay 210 and the fuel cell 220 and is configured to selectively connect the charger 100 or the fuel cell 220 to the multi-converter 230.

For example, the mode switching unit 270 may directly connect the charging relay 210 to the multi-converter 230, or may directly connect the fuel cell 220 to the multi-converter 230.

The battery 250 stores electrical energy of the boosted voltage output from the multi-converter 230. Furthermore, the electrical energy stored in the battery 250 may be supplied to the fuel cell 220 to be used to start (or drive) the fuel cell 220 or to drive the motor 260.

The BMS 290 may check the state of the battery 250, for example, check whether charging of the battery 250 has ended normally, and may output a checking result MCS to the high-level controller 280 to control operation of the battery 250.

The motor controller 240 may be disposed between the multi-converter 230 and the motor 260 to drive the motor 260 using the boosted voltage. For example, the motor controller 240 is configured as a kind of inverter that converts the voltage provided from the battery 250 or the multi-converter 230 into a three-phase alternating current voltage and provides the converted three-phase alternating current voltage to the motor 260, and the motor 260 may be driven by the converted three-phase alternating current voltage. In the present way, the motor 260 may be driven by the power received through the motor controller 240.

The high-level controller 280 is configured to control ON/OFF of each of the charging relay 210 and the mode switching unit 270 and operation of the multi-converter 230.

That is, the charging relay 210 may be turned on or off in response to a control signal output from the high-level controller 280 to connect the charger 100 to the multi-converter 230. Furthermore, under the control of the high-level controller 280, the mode switching unit 270 may connect the charging relay 210 to the multi-converter 230 or connect the fuel cell 220 to the multi-converter 230.

To the present end, for example, the high-level controller 280 may be configured for controlling the charging relay 210 and the mode switching unit 270 based on vehicle ignition ON/OFF state information and vehicle mode information provided from the outside thereof. Under the control of the high-level controller 280, the vehicle 200 may operate in the following three modes.

First, in a fast charging mode in a vehicle ignition off (IG OFF) state, the high-level controller 280 may perform control so that the charging relay 210 is turned on, the mode switching unit 270 interrupts connection between the fuel cell 220 and the multi-converter 230, and the charging relay 210 is connected to the multi-converter 230. Therefore, the charger 100 may be connected to the multi-converter 230, and the fuel cell 220 and the multi-converter 230 may be disconnected from each other. Accordingly, the charging voltage from the charger 100 may be supplied to the multi-converter 230.

Next, in a fuel cell electric vehicle (FCEV) mode in a vehicle ignition on (IG ON) state, the high-level controller 280 may turn the charging relay 210 off to interrupt connection between the charging relay 210 and the multi-converter 230, and may be configured for controlling the mode switching unit 270 to connect the fuel cell 220 to the multi-converter 230. Accordingly, the electrical energy stored in the battery 250 may be converted into power for start of the fuel cell 220, and the converted power may be supplied to the fuel cell 220 to drive the fuel cell 220. Furthermore, the stack voltage corresponding to the power generated by the fuel cell 220 may be supplied to the battery 250 or the motor 260 through the multi-converter 230.

Furthermore, in an EV mode, rather than the FCEV mode, in a vehicle ignition on (IG ON) state, the high-level controller 280 may not control the multi-converter 230, may turn the charging relay 210 off to interrupt connection between the charger 100 and the multi-converter 230, and may be configured for controlling the mode switching unit 270 to interrupt connection between the fuel cell 220 and the multi-converter 230.

Furthermore, the high-level controller 280 may be configured for controlling the multi-converter 230 to diagnose whether the charging relay 210 is welded.

Hereinafter, an exemplary embodiment 200A of the vehicle 200 shown in FIG. 1 will be described.

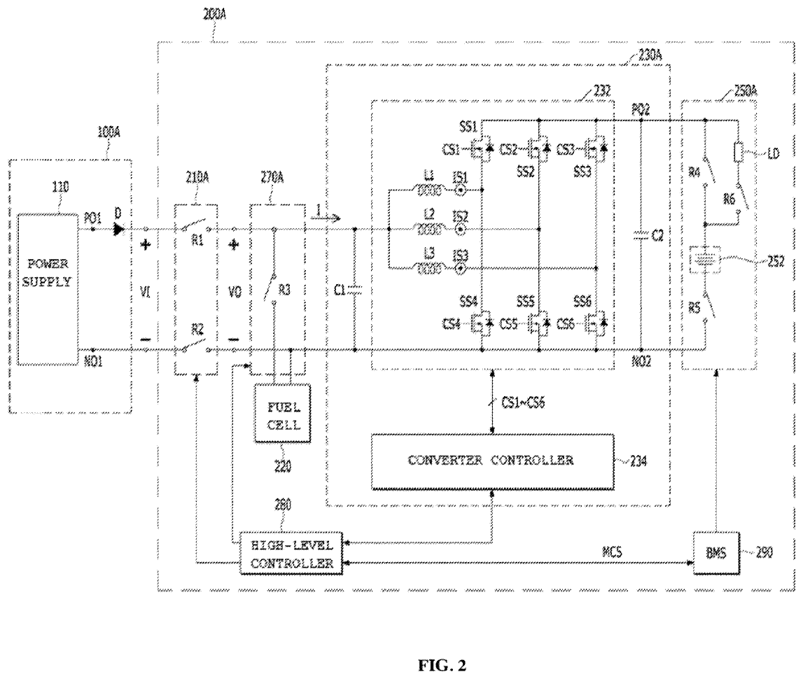

FIG. 2 is a circuit diagram of embodiments 100A and 200A of the charger 100 and the vehicle 200 shown in FIG. 1. The charger 100A and the vehicle 200A shown in FIG. 2 correspond to the exemplary embodiments of the charger 100 and the vehicle 200 shown in FIG. 1, respectively. Illustration of the motor controller 240 and the motor 260 shown in FIG. 1 is omitted in FIG. 2.

The charger 100A includes a power supply 110 and a diode D. The power supply 110 is configured to supply the charging voltage. The charging voltage corresponds to a voltage across a positive output terminal PO1 (hereinafter referred to as a “first positive output terminal”) and a negative output terminal NO1 (hereinafter referred to as a “first negative output terminal”) of the power supply 110. The diode D includes a positive electrode connected to the positive output terminal PO1 of the power supply 110 and a negative electrode connected to the charging relay 210A. The charger 100 shown in FIG. 1 may be implemented in the same form as the charger 100A shown in FIG. 2, but the vehicles 200 and 200A according to the exemplary embodiments are not limited to any specific form of the charger 100.

The charging relay 210A may include first and second charging relays R1 and R2. The first charging relay R1 may be disposed between the negative electrode of the diode D and the multi-converter 230A, and the second charging relay R2 may be disposed between the first negative output terminal NO1 and the multi-converter 230A. For example, each of the first and second charging relays R1 and R2 may be turned on or off in response to a control signal provided from the high-level controller 280.

The mode switching unit 270A may include a mode relay R3. The mode relay R3 is connected between the first positive output terminal PO1 and the fuel cell 220, and the mode switching unit 270A connects the first negative output terminal NO1 to the fuel cell 220. For example, the mode relay R3 may be turned on or off in response to a control signal provided from the high-level controller 280.

When the mode relay R3 is turned off, the charging relay 210A and the multi-converter 230 may be directly connected to each other to form a circuit.

The multi-converter 230A may include a voltage booster (or power module or power level converter) 232 and a converter controller 234. Furthermore, the multi-converter 230A may further include first and second capacitors C1 and C2.

The voltage booster 232 may be connected between the battery 250A and each of the charging relay 210A and the mode switching unit 270A to transmit the charging voltage from the charger 100A to the battery 250A or transmit the boosted voltage, i.e., the charging voltage or stack voltage having the increased level, to the battery 250A. To the present end, the voltage booster 232 may include a plurality of inductors and a plurality of semiconductor switches.

For example, as shown in the drawings, the voltage booster 232 may include first, second, and third inductors L1, L2, and L3 and first, second, third, fourth, fifth and sixth semiconductor switches SS1, SS2, SS3, SS4, SS5 and SS6.

Each of the first, second, and third inductors L1, L2, and L3 includes an end connected to the charging relay 210A. The other end of the first inductor L1 may be connected between the first semiconductor switch SS1 and the fourth semiconductor switch SS4, the other end of the second inductor L2 may be connected between the second semiconductor switch SS2 and the fifth semiconductor switch SS5, and the other end of the third inductor L3 may be connected between the third semiconductor switch SS3 and the sixth semiconductor switch SS6.

For example, the first, second, and third inductors L1, L2, and L3 may form a filter together with the first capacitor C1 and is configured to buffer electrical energy.

The first, second, third, fourth, fifth and sixth semiconductor switches SS1, SS2, SS3, SS4, SS5, and SS6 may be driven in response to first, second, third, fourth, fifth and sixth switch control signals CS1, CS2, CS3, CS4, CS5, and CS6, respectively.

The first semiconductor switch SS1 may be switched on (or turned on) or switched off (or turned off) in response to the first switch control signal CS1, and may be connected between the other end of the first inductor L1 and a positive output terminal PO2 (hereinafter referred to as a “second positive output terminal”) of the voltage booster 232. The first semiconductor switch SS1 may include a gate connected to the first switch control signal CS1, a drain connected to the other end of the first inductor L1, and a source connected to the second positive output terminal PO2.

The second semiconductor switch SS2 may be switched on or switched off in response to the second switch control signal CS2, and may be connected between the other end of the second inductor L2 and the second positive output terminal PO2. The second semiconductor switch SS2 may include a gate connected to the second switch control signal CS2, a drain connected to the other end of the second inductor L2, and a source connected to the second positive output terminal PO2.

The third semiconductor switch SS3 may be switched on or switched off in response to the third switch control signal CS3, and may be connected between the other end of the third inductor L3 and the second positive output terminal PO2. The third semiconductor switch SS3 may include a gate connected to the third switch control signal CS3, a drain connected to the other end of the third inductor L3, and a source connected to the second positive output terminal PO2.

The fourth semiconductor switch SS4 may be switched on or switched off in response to the fourth switch control signal CS4, and may be connected between the other end of the first inductor L1 and a negative output terminal (hereinafter referred to as a “second negative output terminal”) NO2 of the voltage booster 232. The fourth semiconductor switch SS4 may include a gate connected to the fourth switch control signal CS4, a source connected to the other end of the first inductor L1, and a drain connected to the second negative output terminal NO2.

The fifth semiconductor switch SS5 may be switched on or switched off in response to the fifth switch control signal CS5, and may be connected between the other end of the second inductor L2 and the second negative output terminal NO2. The fifth semiconductor switch SS5 may include a gate connected to the fifth switch control signal CS5, a source connected to the other end of the second inductor L2, and a drain connected to the second negative output terminal NO2.

The sixth semiconductor switch SS6 may be switched on or switched off in response to the sixth switch control signal CS6, and may be connected between the other end of the third inductor L3 and the second negative output terminal NO2. The sixth semiconductor switch SS6 may include a gate connected to the sixth switch control signal CS6, a source connected to the other end of the third inductor L3, and a drain connected to the second negative output terminal NO2.

Each of the first, second, third, fourth, fifth and sixth semiconductor switches SS1, SS2, SS3, SS4, SS5 and SS6 may be implemented as an insulated gate bipolar transistor (IGBT) or a field effect transistor (FET). For example, each of the first, second, third, fourth, fifth and sixth semiconductor switches SS1, SS2, SS3, SS4, SS5 and SS6 may be implemented as a transistor, as shown in FIG. 2.

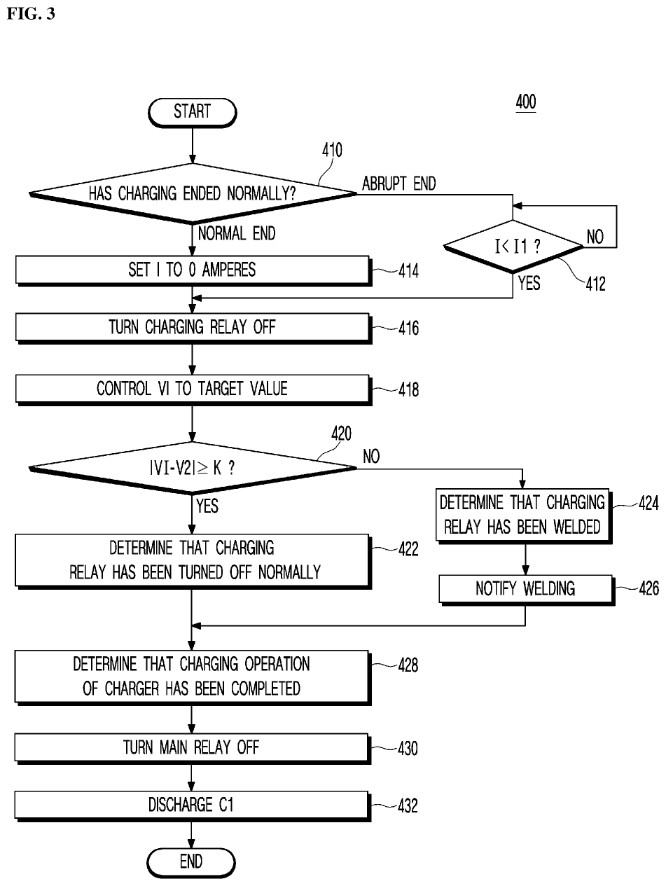

The converter controller 234 may diagnose whether the charging relay 210A is welded using an input-terminal voltage VI of the charging relay 210A (hereinafter referred to as a “third voltage”), an output-terminal voltage VO of the charging relay 210A, and an output-terminal current I of the charging relay 210A. This will be described later with reference to FIG. 3.

For example, the multi-converter 230A may sense the third voltage VI and the output-terminal voltage VO, and may diagnose whether the charging relay 210A is welded using the sensing result.

To achieve the above-described operation, although not shown in the drawings, the converter controller 234 may include a current sensor, a voltage sensor, a driving pulse generation circuit, and an analog-to-digital converter (ADC). The voltage sensor may measure a voltage across both ends of each of the first and second capacitors C1 and C2. The current sensor may be connected to first, second, and third current sensors IS1, IS2, and IS3, and may obtain a current measured by each of the first, second, and third current sensors IS1, IS2, and IS3. Thereafter, the measured voltage may be converted into a digital form in the ADC, and the measured current may be converted into a digital form in the ADC.

The driving pulse generation circuit generates first, second, third, fourth, fifth and sixth switch control signals CS1, CS2, CS3, CS4, CS5, and CS6 through pulse width modulation (PWM), and outputs the first, second, third, fourth, fifth and sixth switch control signals CS1, CS2, CS3, CS4, CS5, and CS6 to the first, second, third, fourth, fifth and sixth semiconductor switches SS1, SS2, SS3, SS4, SS5, and SS6, respectively.

The first current sensor IS1 is connected between the first inductor L1 and each of the first and fourth semiconductor switches SS1 and SS4. The second current sensor IS2 is connected between the second inductor L2 and each of the second and fifth semiconductor switches SS2 and SS5. The third current sensor IS3 is connected between the third inductor L3 and each of the third and sixth semiconductor switches SS3 and SS6. The first, second, and third current sensors IS1, IS2, and IS3 may measure a direct current input to the voltage booster 232, and may output the measured current to the current sensor of the converter controller 234.

The high-level controller 280 may output a charging current target value or a charging voltage target value to the converter controller 234. To follow the charging current target value or the charging voltage target value required by the high-level controller 280, the converter controller 234 may be configured to generate the first, second, third, fourth, fifth and sixth switch control signals CS1 to CS6 for control of voltage/current to control ON/OFF of the first, second, third, fourth, fifth and sixth semiconductor switches SS1, SS2, SS3, SS4, SS5 and SS6.

The converter controller 234 may provide various pieces of state information, such as information related to a charging operation preparation state, a charging operation state, or a charging completion state, to the high-level controller 280. Here, the charging operation preparation state may mean a state in which the charging operation of the charger 100A has been prepared. In other words, the operation preparation state may means a state before the charging operation of the charger 100A starts. Also, the charging operation state may mean a state in which the charging operation of the charger 100A has been processed.

The first capacitor C1 may be connected between the voltage booster 232 and each of the charging relay 210A and the mode switching unit 270A. That is, one end of the first capacitor C1 may be connected to the first charging relay R1, and the other end thereof may be connected to the second charging relay R2. The first capacitor C1 is configured to remove a ripple component from the direct current voltage input to the voltage booster 232, thus preventing the ripple component from being input to the voltage booster 232. Furthermore, the first capacitor C1 may also remove a ripple component from the direct current voltage output from the voltage booster 232 and supplied to the fuel cell 220, thus preventing the ripple component from being input to the fuel cell 220.

The second capacitor C2 may be connected between the voltage booster 232 and the battery 250A. That is, the second capacitor C2 may be connected between the second positive output terminal PO2 and the second negative output terminal NO2. The second capacitor C2 may remove a ripple component from a DC boosted voltage output from the voltage booster 232 and supplied to the battery 250A, thus preventing the ripple component from being input to the battery 250A.

The battery 250A may include main relays R4, R5, and R6 and a power storage unit 252. The first main relay R4 may be connected between the second positive output terminal PO2 and the power storage unit 252, the third main relay R6 and the load LD connected in series to each other may be connected in parallel to the first main relay R4, and the second main relay R5 may be connected between the power storage unit 252 and the second negative output terminal NO2.

The BMS 290 may check whether charging has ended normally, and may output the checking result to the high-level controller 280. Furthermore, the BMS 290 may be configured for controlling ON/OFF of the first, second, and third main relays R4, R5, and R6 included in the battery 250A.

Hereinafter, a relay welding diagnosis method performed in a vehicle according to an exemplary embodiment will be described with reference to the accompanying drawings.

FIG. 3 is a flowchart for explaining a relay welding diagnosis method 400 according to an exemplary embodiment of the present disclosure.

Although the relay welding diagnosis method 400 according to the exemplary embodiment shown in FIG. 3 will be described as being performed in the device 200A shown in FIG. 2 for better understanding, the exemplary embodiment of the present disclosure is not limited thereto. That is, the relay welding diagnosis method 400 according to the exemplary embodiment of the present disclosure may also be performed in a vehicle having a configuration different from that shown in FIG. 2.

The method 400 shown in FIG. 3 may be performed by the high-level controller 280, the converter controller 234, and the BMS 290. Alternatively, the high-level controller 280, the converter controller 234, and the BMS 290 may be integrated in a single controller including at least one processor.

First, the output-terminal current I of the charging relay 210A is controlled depending on whether the charging operation of the charger 100A has ended normally (steps 410 to 414).

In detail, whether the charging operation of the charger 210A has ended normally or abruptly is checked (step 410). For example, the state in which the charging operation of the charger 210A has ended abruptly may be a state in which the charging relay 210A is turned off after the main relays R4, R5, and R6 are automatically turned off when the battery 250A is overheated or overvoltage is applied to the battery 250A. For example, the BMS 290 may perform step 410, and may output the performance result to the high-level controller 280. For example, the overvoltage may mean a voltage greater than the maximum voltage which the battery can endure and the overheat may mean a heat greater than the maximum heat which the batter can endure.

When the charging operation of the charger 100A has ended abruptly, whether the level of the output-terminal current I is less than a predetermined current level I1 is checked (step 412). Thereafter, when the level of the output-terminal current I is less than the predetermined current level I1, the process proceeds to step 416.

Alternatively, when the charging operation of the charger 100A has ended normally, the output-terminal current I is set to 0 amperes (A), and the process proceeds to step 416 (step 414).

After step 414 or when the level of the output-terminal current I is less than the predetermined current level I1, the charging relay 210A is turned off (step 416).

In the state in which the charging operation of the charger 100A has ended abruptly, if the charging relay 210A is turned off when the level of the output-terminal current I is greater than the predetermined current level I1, the charging relay 210A may be damaged. To prevent this, in the state in which the charging operation of the charger 100A has ended abruptly, the charging relay 210A is turned off after the level of the output-terminal current I becomes less than the predetermined current level I1. For example, the predetermined current level I1 may be 3 A to 7 A, for example, 5 A. However, the exemplary embodiment of the present disclosure is not limited thereto.

The above-described steps 412 to 416 may be performed by the high-level controller 280. That is, in response to the result of performing step 410 by the BMS 290, the high-level controller 280 may perform step 412 or 414, and thereafter, may perform step 416.

After step 416, the level of a voltage VO measured at the output terminal of the charging relay 210A (hereinafter referred to as a “first voltage”) is adjusted to a target value, and thereafter, whether the charging relay 210A is welded is diagnosed using a difference in level between a voltage V2 measured again at the output terminal of the charging relay 210A (hereinafter referred to as a “second voltage”) and the third voltage VI measured at the input terminal of the charging relay 210A (steps 418 to 426). Steps 418 to 426 may be performed by the converter controller 234.

In detail, after step 416, the level of the first voltage is controlled to become a target value (step 418). For example, the target value may correspond to half the level of the first voltage.

Thereafter, the second voltage is measured, and whether the absolute value of the difference in level between the measured second voltage V2 and the third voltage VI is greater than or equal to a predetermined value K is checked (step 420). If the charging relay 210A is in a welded state, the difference between the third voltage VI at the input terminal and the second voltage V2 at the output terminal of the charging relay 210A (hereinafter referred to as a “voltage difference”) may be very small even after the level of the first voltage is adjusted to the target value. Therefore, the predetermined value K may be set to be greater than the present very small voltage difference. For example, the predetermined value K may be set to any value among positive integers of 1 or more.

If the absolute value is greater than or equal to the predetermined value K, it is determined that the charging relay 210A has been turned off normally (step 422). The state in which the absolute value is greater than or equal to the predetermined value K means that the absolute value of the difference in level between the third voltage VI at the input terminal and the second voltage V2 at the output terminal of the charging relay 210A is greater than the aforementioned very small voltage difference. Also, this means that the charging relay 210A has been turned off rather than being turned on. Therefore, it may be determined that the charging relay 210A has been turned off normally without being welded.

On the other hand, if the absolute value is less than the predetermined value K, it is determined that the charging relay 210A has been welded (step 424). The state in which the absolute value is less than the predetermined value K means that, since the charging relay 210A is in an ON state, there is little voltage difference between the third voltage VI measured at the input terminal and the second voltage V2 measured at the output terminal. Therefore, it may be determined that the charging relay 210A has been welded.

According to the exemplary embodiment of the present disclosure, after step 424, it may be indicated that the charging relay 210A has been welded (step 426). For example, the converter controller 340 may notify the high-level controller 280 that the charging relay 210A has been welded. Furthermore, the high-level controller 280 may notify a user through a user interface such as a speaker that the charging relay 210A has been welded.

Meanwhile, after step 422 or 426, that is, after diagnosing whether the charging relay 210A is welded, it may be determined that the charging operation of the charger 100A has been completed (step 428). Step 428 may be a step of determining that the vehicle 200A is in a state in which recharging thereof may be performed again, and may be performed by the converter controller 230.

After step 428, the main relays R3, R4, and R5 are turned off (step 430). If the charging operation of the charger 100A ends abruptly, the main relays R4, R5, and R6 are automatically turned off, and thus step 430 does not need to be performed. However, when the charging operation of the charger 100A ends normally, the main relays R4, R5, and R6 are in an ON state, and thus step 430 is performed to turn the main relays R4, R5, and R6 off.

Step 430 may be performed by the BMS 290.

After step 430, the first capacitor C1 is discharged (step 432). Thereafter, the vehicle 200A may be shut down. Step 432 may be performed by the converter controller 230.

To aid in understanding the method 400 shown in FIG. 3, three situations will be described as follows.

A first situation is defined as a situation in which the charging operation of the charger 100A has ended normally.

In the instant case, the third voltage VI at the input terminal of the charging relay 210A may be 0 volts, and the first voltage V1 at the output terminal of the charging relay 210A may be 400 volts. In the instant case, step 418 is performed to control the level of the first voltage V1, i.e., 400 volts, to the target value, i.e., 200 volts.

Thereafter, when the second voltage measured again at the output terminal of the charging relay 210A is 200 volts and the third voltage VI is 0 volts, the absolute value is greater than or equal to the predetermined value K, and therefore, it is determined that the charging relay 210A has been turned off normally (step 422).

A second situation is defined as a situation in which the charging operation of the charger 100A has ended abruptly and the charging relay 210A is not welded.

In the instant case, the third voltage VI at the input terminal of the charging relay 210A may be 400 volts, and the first voltage V1 at the output terminal of the charging relay 210A may be 400 volts. In the instant case, step 418 is performed to control the level of the first voltage V1, i.e., 400 volts, to the target value, i.e., 200 volts.

Thereafter, when the second voltage measured at the output terminal of the charging relay 210A is 200 volts and the third voltage VI is 400 volts, the absolute value is greater than or equal to the predetermined value K, and therefore, it is determined that the charging relay 210A has been turned off normally (step 422).

A third situation is defined as a situation in which the charging operation of the charger 100A has ended abruptly and the charging relay 210A has been welded.

In the instant case, the third voltage VI at the input terminal of the charging relay 210A may be 400 volts, and the first voltage V1 at the output terminal of the charging relay 210A may be 400 volts. In the instant case, step 418 is performed to control the level of the first voltage V1, i.e., 400 volts, to the target value, i.e., 200 volts.

Thereafter, since the second voltage measured at the output terminal of the charging relay 210A is 200 volts and the charging relay 210A is in a welded state, i.e., an ON state, the third voltage VI also becomes 200 volts rather than 400 volts, and thus the absolute value is less than the predetermined value K. Therefore, it is determined that the charging relay 210A has been welded, rather than being turned off normally (step 426).

In a situation in which the charging operation has ended abruptly due to overheating of the battery 250 or 250A or application of overvoltage thereto, when the third voltage VI at the input terminal of the charging relay 210 or 210A is temporarily maintained at 400 volts, the third voltage VI at the input terminal of the charging relay 210 or 210A and the first voltage V1 at the output terminal of the charging relay 210 or 210A may be temporarily maintained at 400 volts. In the present situation, because the third voltage VI and the first voltage V1 are identical to each other, it may be erroneously determined that the charging relay 210 or 210A has been welded even when the charging relay 210 or 210A has been turned off normally.

However, according to the exemplary embodiment of the present disclosure, it may be possible to accurately determine whether the charging relay 210 or 210A is turned off normally or is welded by performing steps 418 to 424.

As a result, the vehicle 200 or 200A according to the exemplary embodiment described above may accurately and efficiently diagnose whether the charging relay 210 or 210A is welded by eliminating the possibility of misdiagnosis of welding of the charging relay 210 or 210A regardless of the state of voltage remaining in the charger 100, improving charging stability, and consequently improving the marketability of the product.

As is apparent from the above description, according to a vehicle including a relay welding diagnosis function and a relay welding diagnosis method performed in the vehicle of the embodiments, it may be possible to accurately and efficiently diagnose whether a charging relay is welded by eliminating the possibility of misdiagnosis of welding of the charging relay regardless of the state of voltage remaining in a charger, whereby charging stability may be improved, and consequently the marketability of the product may be improved.

However, the effects achievable through the present disclosure are not limited to the above-mentioned effects, and other effects not mentioned herein will be clearly understood by those skilled in the art from the above description.

Furthermore, the term related to a control device such as “controller”, “control apparatus”, “control unit”, “control device”, “control module”, or “server”, etc refers to a hardware device including a memory and a processor configured to execute one or more steps interpreted as an algorithm structure. The memory stores algorithm steps, and the processor executes the algorithm steps to perform one or more processes of a method in accordance with various exemplary embodiments of the present disclosure. The control device according to exemplary embodiments of the present disclosure may be implemented through a nonvolatile memory configured to store algorithms for controlling operation of various components of a vehicle or data about software commands for executing the algorithms, and a processor configured to perform operation to be described above using the data stored in the memory. The memory and the processor may be individual chips. Alternatively, the memory and the processor may be integrated in a single chip. The processor may be implemented as one or more processors. The processor may include various logic circuits and operation circuits, may be configured for processing data according to a program provided from the memory, and may be configured to generate a control signal according to the processing result.

The control device may be at least one microprocessor operated by a predetermined program which may include a series of commands for carrying out the method included in the aforementioned various exemplary embodiments of the present disclosure.

The aforementioned invention can also be embodied as computer readable codes on a computer readable recording medium. The computer readable recording medium is any data storage device that can store data which may be thereafter read by a computer system and store and execute program instructions which may be thereafter read by a computer system. Examples of the computer readable recording medium include Hard Disk Drive (HDD), solid state disk (SSD), silicon disk drive (SDD), read-only memory (ROM), random-access memory (RAM), CD-ROMs, magnetic tapes, floppy discs, optical data storage devices, etc and implementation as carrier waves (e.g., transmission over the Internet). Examples of the program instruction include machine language code such as those generated by a compiler, as well as high-level language code which may be executed by a computer using an interpreter or the like.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

Hereinafter, the fact that pieces of hardware are coupled operably may include the fact that a direct and/or indirect connection between the pieces of hardware is established by wired and/or wirelessly.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A vehicle including a relay welding diagnosis function and configured to be connectable to a charger providing a charging voltage, the vehicle comprising:
a fuel cell configured to provide a stack voltage;
a multi-converter configured to increase a level of the charging voltage or the stack voltage and to output the charging voltage or the stack voltage having the increased level as a boosted voltage;
a charging relay disposed between the charger and the multi-converter; and
a battery configured to store electrical energy of the boosted voltage,
wherein the multi-converter includes:
a voltage booster connected between the charging relay and the battery and configured to generate the boosted voltage; and
a converter controller configured to diagnose whether the charging relay is welded using a result of sensing an input-terminal voltage and an output-terminal voltage of the charging relay.

2. The vehicle of claim 1, further including a mode switching unit configured to selectively connect the fuel cell to the multi-converter.

3. The vehicle of claim 2, further including a high-level controller configured to control ON/OFF of the charging relay and the mode switching unit and to control the converter controller to diagnose whether the charging relay is welded.

4. The vehicle of claim 3, wherein the multi-converter further includes a first capacitor connected between the voltage booster and the charging relay.

5. The vehicle of claim 4, wherein the multi-converter further includes a second capacitor connected between the voltage booster and the battery.

6. The vehicle of claim 3, further including a battery management system configured to check whether charging of the battery ends normally, to output a checking result to the high-level controller, and to control ON/OFF of the main relay included in the battery.

7. The vehicle of claim 1, wherein the converter controller is further configured to diagnose whether the charging relay is welded by adjusting a level of a first voltage measured at an output terminal of the charging relay to a target value and using a difference in level between a second voltage measured again at the output terminal of the charging relay and a third voltage measured at an input terminal of the charging relay.

8. The vehicle of claim 7, wherein the converter controller is further configured to diagnose whether the charging relay is welded, by:
controlling the level of the first voltage to the target value;
measuring the second voltage;
checking whether an absolute value of the difference in level between the second voltage and the third voltage is greater than or equal to a predetermined value;
determining that the charging relay has been turned off normally in response that the absolute value is greater than or equal to the predetermined value; and
determining that the charging relay has been welded in response that the absolute value is less than the predetermined value.

9. A relay welding diagnosis method performed in the vehicle described in claim 4, the method comprising:
controlling an output-terminal current of the charging relay according as charging operation of the charger ends normally;
turning the charging relay off; and
diagnosing whether the charging relay is welded by adjusting a level of a first voltage measured at an output terminal of the charging relay to a target value and using a difference in level between a second voltage measured again at the output terminal of the charging relay and a third voltage measured at an input terminal of the charging relay.

10. The method of claim 9, wherein the controlling the output-terminal current includes:
checking whether the charging operation ends normally or abruptly;
setting the output-terminal current to 0 amperes when the charging operation has ended normally; and
checking whether the output-terminal current is less than a predetermined current level in response that the charging operation has ended abruptly.

11. The method of claim 9, wherein the diagnosing whether the charging relay is welded includes:
controlling the level of the first voltage to the target value;
measuring the second voltage;
checking whether an absolute value of the difference in level between the second voltage and the third voltage is greater than or equal to a predetermined value;
determining that the charging relay has been turned off normally when the absolute value is greater than or equal to the predetermined value; and
determining that the charging relay has been welded when the absolute value is less than the predetermined value.

12. The method of claim 11, wherein the target value corresponds to half the level of the first voltage.

13. The method of claim 11, wherein the diagnosing whether the charging relay is welded further includes notifying that the charging relay has been welded.

14. The method of claim 9, further including, after the diagnosing whether the charging relay is welded, determining that the charging operation of the charger has been completed.

15. The method of claim 14, further including turning a main relay included in the battery off.

16. The method of claim 15, further including discharging the first capacitor.
